(19) United States
(12) Patent Application Publication
(10) Pub. No.: US 2015/0214415 A1
(43) Pub. Date: Jul. 30, 2015

(54) PHOTOCONDUCTIVE ANTENNA, CAMERA, IMAGING DEVICE, AND MEASUREMENT DEVICE

(71) Applicant: SEIKO EPSON CORPORATION, Tokyo (JP)

(72) Inventor: Satoshi TAKENAKA, Chino-shi (JP)

(21) Appl. No.: 14/609,310

(22) Filed: Jan. 29, 2015

(30) Foreign Application Priority Data
Jan. 30, 2014 (JP) 2014-015707

(51) Int. Cl. H01L 31/16; G01N 21/3581

(52) U.S. Cl. CPC H01L 31/16; G01N 21/3581; G01N 2201/061; G01N 2201/0696

(57) ABSTRACT

A photoconductive antenna that generates a terahertz wave by irradiation with a light pulse, includes: a first layer that has carriers formed therein by irradiation with the light pulse; a second layer, located above the first layer, which has carrier mobility larger than carrier mobility of the first layer; and a first electrode and a second electrode, located above the second layer, which apply a voltage to the second layer.

### BACKGROUND

1. Technical Field

The present invention relates to a photoconductive antenna, a camera, an imaging device, and a measurement device.

2. Related Art

In recent years, terahertz waves which are electromagnetic waves having a frequency equal to or greater than 100 GHz and equal to or less than 30 THz have attracted attention. The terahertz waves can be used in, for example, various types of measurement such as imaging and spectroscopic measurement, non-destructive tests, and the like.

Terahertz wave generation devices that generate such terahertz waves include, for example, a light pulse generation device that generates a light pulse having a pulse width of approximately subpicoseconds (several hundred femtoseconds), and a photoconductive antenna that generates a terahertz wave by irradiation with the light pulse generated in the light pulse generation device.

For example, JP-A-2009-124437 discloses a photoconductive antenna including a semi-insulating GaAs substrate, a GaAs (LT-GaAs) layer formed on the semi-insulating GaAs substrate by a low-temperature MBE (molecular beam epitaxy) method, and a pair of electrodes formed on the LT-GaAs layer. Further, JP-A-2009-124437 discloses that free carriers excited in the LT-GaAs layer are accelerated by an electric field caused by a bias voltage, whereby a current flows, and a terahertz wave is generated due to a change in this current.

The intensity of the terahertz wave which is generated in the above-mentioned photoconductive antenna is preferably large, whereby it is possible to realize a camera, an imaging device, and a measurement device having, for example, high detection sensitivity.

It is known that the intensity of a terahertz wave which is generated in a photoconductive antenna is dependent on the carrier mobility of a layer through which carriers transfer (travel) in the photoconductive antenna. That is, as the carrier mobility of the layer becomes larger, the intensity of the terahertz wave which is generated in the photoconductive antenna becomes larger.

In the photoconductive antenna disclosed in JP-A-2009-124437, since the carrier mobility (electron mobility) of the LT-GaAs layer has a small rate of 100 cm²/Vs to 150 cm²/Vs, the time variation of a photocurrent decreases, and thus it may not be possible to generate a terahertz wave having a large intensity. For this reason, it may not be possible to realize a camera, an imaging device, and a measurement device which have high detection sensitivity.

### SUMMARY

An advantage of some aspects of the invention is to provide a photoconductive antenna which is capable of enhancing carrier mobility more than in the related art, and generating a terahertz wave having a large intensity. In addition, another advantage of some aspects of the invention is to provide a camera, an imaging device, and a measurement device which include the aforementioned photoconductive antenna.

An aspect of the invention is directed to a photoconductive antenna that generates a terahertz wave by irradiation with a light pulse, including: a first layer that has carriers formed therein by irradiation with the light pulse; a second layer, located above the first layer, which has carrier mobility larger than carrier mobility of the first layer; and a first electrode and a second electrode, located above the second layer, which apply a voltage to the second layer.

In such a photoconductive antenna, a layer having carriers formed therein and a layer having the carriers transferring therethrough by an applied voltage are separately provided. Therefore, in such a photoconductive antenna, a large number of carriers can be formed in the first layer, and the carriers can transfer through the second layer having large carrier mobility. Therefore, in such a photoconductive antenna, it is possible to enhance the carrier mobility of the layer through which the carriers transfer, and to generate (radiate) a terahertz wave having a large intensity.

Meanwhile, in the disclosure according to the invention, when the wording “above” is used in, for example, the phrase “form another specific thing (hereinafter, referred to as “B”) “above” a specific thing (hereinafter, referred to as “A”)” or the like, a case where B is formed directly on A and a case where B is formed on A through another thing are assumed to be included, and the wording “above” is used.

In the photoconductive antenna according to the aspect of the invention, the first layer may be constituted by a semi-insulating substrate.

In such a photoconductive antenna, it is possible to generate a terahertz wave having a large intensity.

In the photoconductive antenna according to the aspect of the invention, the first layer may be formed of GaAs.

In such a photoconductive antenna, it is possible to form a large number of carriers in the first layer.

In the photoconductive antenna according to the aspect of the invention, the first layer may be formed of silicon.

In such a photoconductive antenna, since a substrate can be formed at a lower cost, for example, than in a case where the first layer is formed of GaAs, and can be formed in a general semiconductor manufacturing process, it is possible to improve a reduction in cost.

In the photoconductive antenna according to the aspect of the invention, the second layer may be formed of a material containing carbon as a main ingredient.

In such a photoconductive antenna, it is possible to generate a terahertz wave having a large intensity.

In the photoconductive antenna according to the aspect of the invention, the second layer may be formed of graphene.

In such a photoconductive antenna, the carrier mobility of the layer through which the carriers transfer can be enhanced more than in a case where an LT-GaAs layer or a layer formed of semi-insulating GaAs is used as the layer through which the carriers transfer.

In the photoconductive antenna according to the aspect of the invention, the second layer may include a carbon nanotube.

In such a photoconductive antenna, the carrier mobility of the layer through which the carriers transfer can be enhanced more than in a case where an LT-GaAs layer or a layer formed of semi-insulating GaAs is used as the layer through which the carriers transfer.

The photoconductive antenna according to the aspect of the invention may further include an insulating layer which is located between the second layer and the first electrode, and between the second layer and the second electrode.

In such a photoconductive antenna, it is possible to enhance a breakdown voltage. As a result, in such a photoconductive antenna, it is possible to have high reliability.

Another aspect of the invention is directed to a terahertz wave generation device including: a light pulse generation device that generates a light pulse; and the photoconductive antenna according to the above aspects which generates the terahertz wave by irradiation with the light pulse.

In such a terahertz wave generation device, since the photoconductive antenna according to the above aspects is included, it is possible to generate a terahertz wave having a large intensity.

Still another aspect of the invention is directed to a camera including: a light pulse generation device that generates a light pulse; the photoconductive antenna according to the above aspects which generates the terahertz wave by irradiation with the light pulse; a terahertz wave detection portion that detects the terahertz wave emitted from the photoconductive antenna and passing through an object or the terahertz wave reflected from the object; and a storage portion that stores detection results of the terahertz wave detection portion.

In such a camera, since the photoconductive antenna according to the above aspects is included, it is possible to have high detection sensitivity.

Yet another aspect of the invention is directed to an imaging device including: a light pulse generation device that generates a light pulse; the photoconductive antenna according to the above aspects which generates the terahertz wave by irradiation with the light pulse; a terahertz wave detection portion that detects the terahertz wave emitted from the photoconductive antenna and passing through an object or the terahertz wave reflected from the object; and an image forming portion that generates an image of the object on the basis of detection results of the terahertz wave detection portion.

In such an imaging device, since the photoconductive antenna according to the above aspects is included, it is possible to have high detection sensitivity.

Still yet another aspect of the invention is directed to a measurement device including: a light pulse generation device that generates a light pulse; the photoconductive antenna according to the above aspects which generates the terahertz wave by irradiation with the light pulse; a terahertz wave detection portion that detects the terahertz wave emitted from the photoconductive antenna and passing through an object or the terahertz wave reflected from the object; and a measurement portion that measures the object on the basis of detection results of the terahertz wave detection portion.

In such a measurement device, since the photoconductive antenna according to the above aspects is included, it is possible to have high detection sensitivity.

### BRIEF DESCRIPTION OF THE DRAWINGS

The invention will be described with reference to the accompanying drawings, wherein like numbers reference like elements.

FIG. 1 is a cross-sectional view schematically illustrating a photoconductive antenna according to the present embodiment.

FIG. 2 is a plan view schematically illustrating the photoconductive antenna according to the present embodiment.

FIG. 3 is a cross-sectional view schematically illustrating a process of manufacturing the photoconductive antenna according to the present embodiment.

FIG. 4 is a cross-sectional view schematically illustrating a process of manufacturing the photoconductive antenna according to the present embodiment.

FIG. 5 is a cross-sectional view schematically illustrating a process of manufacturing the photoconductive antenna according to the present embodiment.

FIG. 6 is a cross-sectional view schematically illustrating a photoconductive antenna according to a first modification example of the present embodiment.

FIG. 7 is a cross-sectional view schematically illustrating a photoconductive antenna according to second modification example of the present embodiment.

FIG. 8 is a diagram illustrating a configuration of a terahertz wave generation device according to the present embodiment.

FIG. 9 is a block diagram illustrating an imaging device according to the present embodiment.

FIG. 10 is a plan view schematically illustrating a terahertz wave detection portion of the imaging device according to the present embodiment.

FIG. 11 is a graph illustrating a spectrum of an object in a terahertz band.

FIG. 12 is an image diagram illustrating a distribution of substances A, B and C of the object.

FIG. 13 is a block diagram illustrating a measurement device according to the present embodiment.

FIG. 14 is a block diagram illustrating a camera according to the present embodiment.

FIG. 15 is a perspective view schematically illustrating the camera according to the present embodiment.

### DESCRIPTION OF EXEMPLARY EMBODIMENTS

Hereinafter, preferred embodiments of the invention will be described in detail with reference to the accompanying drawings. Meanwhile, the embodiments described below are not unduly limited to the disclosure of the invention described in the appended claims. In addition, all the configurations described below are not necessarily the essential components of the invention.

### 1. Photoconductive Antenna

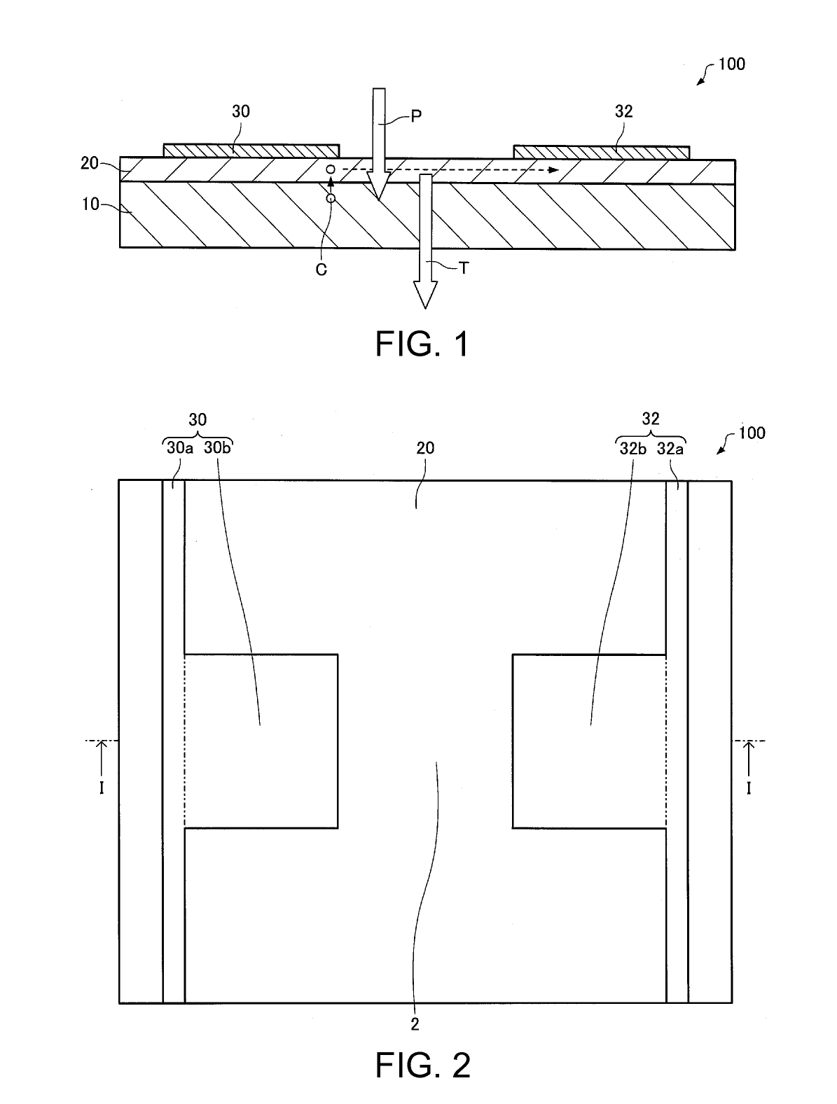

First, a photoconductive antenna according to the present embodiment will be described with reference to the accompanying drawings. FIG. 1 is a cross-sectional view schematically illustrating a photoconductive antenna 100 according to the present embodiment. FIG. 2 is a plan view schematically illustrating the photoconductive antenna 100 according to the present embodiment. Meanwhile, FIG. 1 is a cross-sectional view taken along line I-I of FIG. 2.

As shown in FIGS. 1 and 2, the photoconductive antenna 100 includes a first layer 10, a second layer 20, a first electrode 30, and a second electrode 32. The photoconductive antenna 100 generates a terahertz wave T by irradiation with a light pulse P.

Meanwhile, the term “light pulse” as used herein refers to light of which the intensity changes drastically in a short period of time. The pulse width (full width at half maximum: FWHM) of the light pulse P is not particularly limited, but is, for example, equal to or greater than 1 fs (femtosecond) and equal to or less than 800 fs. In addition, the “terahertz wave” refers to an electromagnetic wave having a frequency of equal to or greater than 100 GHz and equal to or less than 30 THz, particularly, an electromagnetic wave having a frequency of equal to or greater than 300 GHz and equal to or less than 3 THz.

The first layer 10 is constituted by, for example, a semi-insulating substrate. The term “semi-insulating substrate” as used herein refers to a substrate which is constituted by a compound-semiconductor, and a high-resistance (for example, specific resistance is equal to or greater than 10⁷ Ω·cm) substrate. Specifically, the semi-insulating substrate constituting the first layer 10 is a GaAs substrate which does not contain impurities (which is not doped with impurities). That is, specifically, the first layer 10 is formed of GaAs. GaAs constituting the first layer 10 may be in a stoichiometric state. That is, Ga and As constituting the first layer 10 may be present at a proportion of 1:1. When the first layer 10 is formed of a semi-insulating GaAs substrate, the carrier mobility (electron mobility) of the first layer 10 is, for example, equal to or greater than 3,000 cm²/Vs and equal to or less than 8,500 cm²/Vs. The semi-insulating substrate constituting the first layer 10 may be an InP substrate, an InAs substrate, or an InSb substrate.

Meanwhile, the term “carrier mobility” as used herein refers to a distance for which carriers (electrons and holes) transfer per unit hour under a unit electric field intensity when the carriers transfer through a solid-state substance, and a tendency for the carriers to transfer through a solid-state substance. Hereinafter, the carrier mobility refers to electron mobility.

The first layer 10 may be constituted by a silicon (Si) substrate. That is, the first layer 10 may be formed of silicon. The silicon constituting the first layer 10 may be single crystal silicon, polycrystalline silicon, or amorphous silicon. When the first layer 10 is formed of a single crystal silicon substrate, the carrier mobility of the first layer 10 is, for example, equal to or greater than 1,000 cm²/Vs and equal to or less than 2,000 cm²/Vs.

The first layer 10 forms carriers C by irradiation with the light pulse P. Specifically, the first layer 10 forms a plurality of (a large number of) carriers C. The first layer 10 transmits at least a portion of the terahertz wave T.

The second layer 20 is located on the first layer 10. The second layer 20 has carrier mobility larger than the carrier mobility of the first layer 10. The second layer 20 is formed of a material containing carbon as a main ingredient. Here, the material containing carbon as a main ingredient may be a material composed of only carbon, and may be a material containing carbon as a main ingredient and containing elements other than carbon as accessory ingredients. The material constituting second layer 20 may be crystalline. Meanwhile, when the second layer 20 has carrier mobility larger than the carrier mobility of the first layer 10, the second layer may be constituted by materials other than the material containing carbon as a main ingredient.

The second layer 20 is formed of, for example, graphene. The “graphene” as used herein refers to a layer having a thickness of one atom in which carbon atoms are lined up in a hexagonal lattice shape. The second layer 20 may be constituted by a graphene monolayer, and may be constituted by a plurality of graphenes laminated. When the second layer 20 is formed of graphene, the carrier mobility of the second layer 20 is, for example, approximately 200,000 cm²/V. In this case, the intensity ratio R of the terahertz wave generated in the photoconductive antenna 100 is, for example, equal to or greater than 1,000 and equal to or less than 2,000. The “intensity ratio R” as used herein refers to a ratio (I₁₀₀/I₀) of the intensity I₁₀₀ of the terahertz wave generated in the photoconductive antenna 100 to the intensity I₀ of a terahertz wave generated in a photoconductive antenna in which carriers are formed in an LT-GaAs layer and the carriers transfer through the LT-GaAs layer by an applied voltage.

Meanwhile, the graphene may be influenced by an underlying layer (layer where the graphene is provided). For example, when the graphene is provided on a SiO₂ layer, the carrier mobility of the graphene is, for example, approximately 40,000, and the intensity ratio R of the terahertz wave is, for example, equal to or greater than 200 and equal to or less than 400.

The second layer 20 may be configured to include a carbon nanotube (CNT). The “carbon nanotube” as used herein refers to a substance in which a six-membered ring network (graphene sheet) created by carbon is formed in a monolayer or multilayer coaxial tube shape. When the second layer 20 is configured to include a carbon nanotube, the carrier mobility of the second layer 20 is, for example, approximately 30,000 cm²/V, and the intensity ratio R of the terahertz wave is, for example, approximately 200.

The second layer 20 may be constituted by diamond-like carbon (DLC). The “diamond-like carbon” as used herein refers to an amorphous hard film which is chiefly formed of hydrocarbon or an allotrope of carbon, and has a structure in which both diamond bonding (SP3 bonding) and graphite bonding (SP2 bonding) are mixed.

The second layer 20 transmits at least a portion of the light pulse P. The transmittance of the second layer 20 to the light pulse P is, for example, equal to or greater than 80%. The wavelength of the light pulse P is a wavelength which is absorbed in the first layer 10, and is for example, approximately 800 nm. When the second layer 20 is formed of graphene, the transmittance of the second layer 20 to infrared light (light having a wavelength of 700 nm to 900 nm) is, for example, equal to or greater than 70% and equal to or less than 95%. The thickness of the second layer 20 is, for example, equal to or less than several hundreds nm, and specifically, equal to or more than one atomic layer and equal to or less than several tens nm.

Meanwhile, although not shown in the drawing, when the transmittance of the second layer 20 to the light pulse P is low, the second layer 20 is provided with an opening, and the first layer 10 may be irradiated by passing the light pulse P through the opening.

The first electrode 30 and the second electrode 32 are located on the second layer 20. The electrodes 30 and 32 are electrodes that apply a voltage to the second layer 20. The electrodes 30 and 32 may apply a direct-current (DC) voltage to the second layer 20, and may apply an alternating-current (AC) voltage thereto. The electrodes 30 and 32 may be brought into ohmic contact with the second layer 20.

The first electrode 30 and the second electrode 32 are, for example, an Au layer, a Pt layer, a Ti layer, an Al layer, a Cu layer, a Cr layer, or a laminated body thereof. For example, when the laminated body of an Au layer and a Cr layer is used as the electrodes 30 and 32, the Cr layer can improve adhesion between the second layer 20 and the Au layer.

As shown in FIG. 2, the first electrode 30 includes a first base 30a and a first protruding portion 30b which protrudes from the first base 30a to the second electrode 32 side. The second electrode 32 includes a second base 32a and a second protruding portion 32b which protrudes from the second base 32a to the first electrode 30 side. A distance between the protruding portions 30b and 32b is, for example, equal to or greater than 1 μm and equal to or less than 100 μm, and more specifically, approximately 5 μm. In the shown example, the planar shape of the protruding portions 30b and 32b (shape when seen from the lamination direction of the first layer 10 and the second layer 20) is rectangular. That is, the photoconductive antenna 100 is a dipole PCA. In the shown example, the bases 30a and 32a have a belt-like planar shape.

Meanwhile, although not shown in the drawing, the first protruding portion 30b may have a trapezoidal planar shape having a narrower width toward the second electrode 32 side. Similarly, the second protruding portion 32b may have a trapezoidal planar shape having a narrower width toward the first electrode 30 side. That is, the photoconductive antenna 100 may be a bow-tie PCA.

Next, operations of the photoconductive antenna 100 will be described. In a state where a voltage is applied to the second layer 20 by the electrodes 30 and 32, a region 2 located between the protruding portions 30b and 32b is irradiated with the light pulse P when seen in plan view (when seen from the lamination direction of the first layer 10 and the second layer 20). The light pulse P passes through the second layer 20, and the first layer 10 is irradiated with the light pulse.

The carriers (for example electrons) C are instantaneously generated in the first layer 10 by irradiation with the light pulse P. Since the carrier mobility of the second layer 20 is larger than the carrier mobility of the first layer 10, the carriers C transfer from the first layer 10 to the second layer 20. The carriers having transferred to the second layer 20 are accelerated by the voltage applied by the electrodes 30 and 32 and transfer (travel), and an instantaneous current (photocurrent) flows in the second layer 20. The terahertz wave T having an intensity proportional to the time variation of the photocurrent is generated. The time variation of the photocurrent is proportional to the carrier mobility of the second layer 20. Therefore, the terahertz wave T having an intensity proportional to the carrier mobility of the second layer 20 is generated in the photoconductive antenna 100.

Meanwhile, in the shown example, the carriers C transfer from the first electrode 30 side toward the second electrode 32 side, but may transfer from the second electrode 32 side toward the first electrode 30 side. In addition, insofar as a position or an area which is irradiated with the light pulse P is the region 2 between the protruding portions 30b and 32b when seen in plan view, it is not particularly limited.

In addition, although not shown in the drawing, carriers may be generated in the second layer 20 by irradiation with the light pulse P. However, the number of carriers generated in the second layer 20 (for example, the number of carriers generated in a unit volume) is smaller than the number of carriers generated in the first layer 10.

The photoconductive antenna 100 has, for example, the following features.

The photoconductive antenna 100 includes the first layer 10 having carriers formed therein by irradiation with the light pulse P, and the second layer 20, located on the first layer 10, which has carrier mobility larger than the carrier mobility of the first layer 10. In this manner, the photoconductive antenna 100 is separately provided with a layer having carriers formed therein and a layer having the carriers transferring therethrough by an applied voltage. Therefore, in the photoconductive antenna 100, a large number of carriers can be formed in the first layer 10, and the carriers can transfer through the second layer 20 having large carrier mobility. Therefore, in the photoconductive antenna 100, it is possible to enhance the carrier mobility of the layer through which the carriers transfer, and to generate the terahertz wave T having a large intensity.

In the photoconductive antenna 100, the first layer is constituted by a semi-insulating substrate, and specifically, is formed of GaAs. Therefore, in the photoconductive antenna 100, a large number of carriers can be formed in the first layer 10.

In the photoconductive antenna 100, the first layer 10 is formed of, for example, silicon. Therefore, in the photoconductive antenna 100, since a substrate can be formed at a lower cost, for example, than in a case where the first layer 10 is formed of GaAs, and can be formed in a general semiconductor manufacturing process, it is possible to improve a reduction in cost.

In the photoconductive antenna 100, the second layer 20 is formed of a material containing carbon as a main ingredient. Specifically, the second layer 20 is formed of graphene. Alternatively, the second layer 20 is configured to include a carbon nanotube. Alternatively, the second layer 20 is formed of diamond-like carbon. Therefore, in the photoconductive antenna 100, the carrier mobility of the layer through which the carriers transfer can be enhanced more than in a case where an LT-GaAs layer or a layer formed of semi-insulating GaAs is used as the layer through which the carriers transfer.

### 2. Method of Manufacturing of Photoconductive Antenna

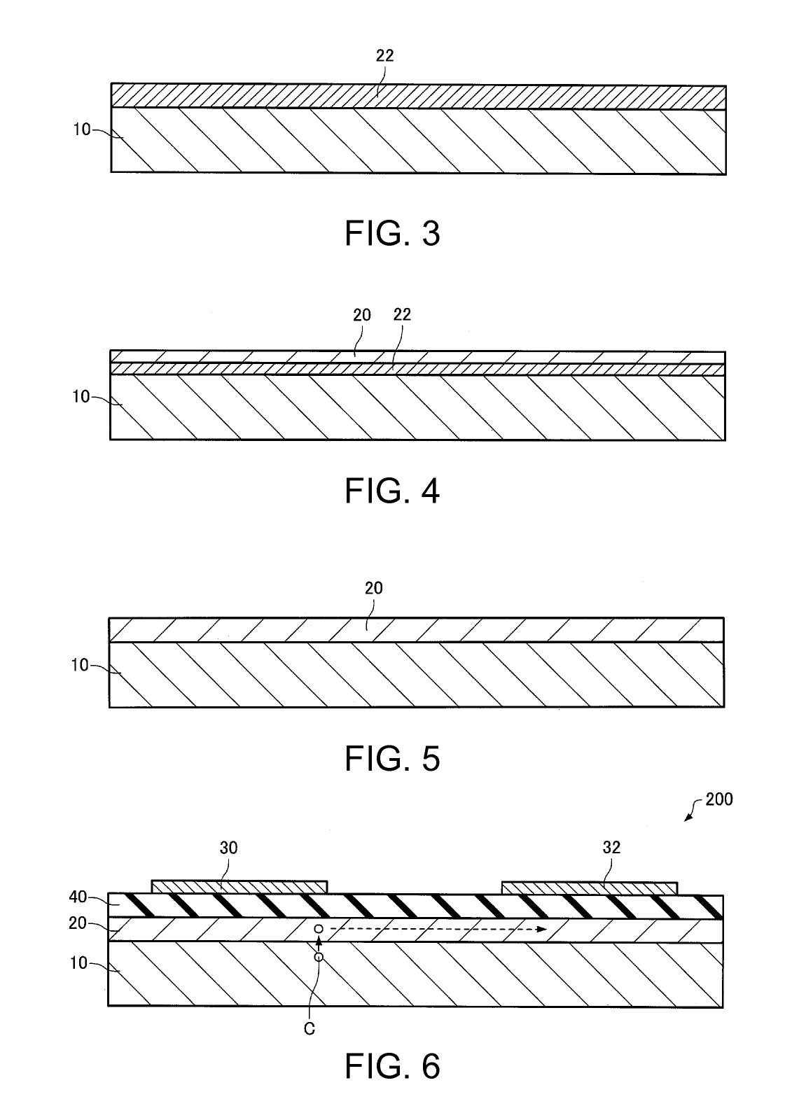

Next, a method of manufacturing the photoconductive antenna according to the present embodiment will be described with reference to the accompanying drawings. FIGS. 3 to 5 are cross-sectional views schematically illustrating a process of manufacturing the photoconductive antenna 100 according to the present embodiment, and correspond to FIG. 1. Hereinafter, a case where a layer formed of graphene is used as the second layer 20 will be described.

As shown in FIG. 3, an SiC layer 22 is formed on the first layer 10. The SiC layer 22 is formed by, for example, a CVD (Chemical Vapor Deposition) method or a PECVD (Plasma-Enhanced Chemical Vapor Deposition) method. When the first layer 10 is formed of silicon, the SiC layer 22 may be epitaxially grown on the first layer 10 by, for example, an MOCVD (Metal Organic Chemical Vapor Deposition) method, an MBE (Molecular Beam Epitaxy) method, or the like.

As shown in FIGS. 4 and 5, heat treatment is performed, and the SiC layer 22 is changed into the second layer 20 formed of graphene. For example, as shown in FIG. 4, the SiC layer 22 is changed into the second layer 20 from the upper surface side by heat treatment. Thereafter, as shown in FIG. 5, the entirety of the SiC layer 22 is changed into the second layer 20. Specifically, Si of SiC layer 22 is taken off by heat treatment of approximately 1,000° C., and the second layer 20 formed of graphene is formed. The heat treatment is performed using, for example, laser annealing or lamp annealing.

Meanwhile, while the entirety of the SiC layer 22 is not changed into the second layer 20 as shown in FIG. 5, the heat treatment may be stopped in a state where the SiC layer 22 is located between the first layer 10 and the second layer 20, for example, as shown in FIG. 4.

As shown in FIG. 1, the first electrode 30 and second electrode 32 are formed on the second layer 20. The electrodes 30 and 32 are formed by, for example, a combination of a vacuum vapor deposition method and a lift-off method, or the like.

The photoconductive antenna 100 can be manufactured by the above processes.

Meanwhile, a layer formed of carbon (carbon film) may be formed on the first layer 10 by, for example, an electron beam (EB) evaporation method, and the second layer 20 formed of graphene may be formed by heat-treating the carbon film.

In addition, when a carbon nanotube is used as the second layer 20, the second layer 20 is formed by, for example, a laser ablation method or a CVD method. In addition, when diamond-like carbon is used as the second layer 20, the second layer 20 is formed by, for example, a CVD method, a vacuum vapor deposition method, or a sputtering method.

### 3. Modification Example of Photoconductive Antenna

### 3.1. First Modification Example

Next, a photoconductive antenna according to a first modification example of the present embodiment will be described with reference to the accompanying drawings. FIG. 6 is a cross-sectional view schematically illustrating a photoconductive antenna 200 according to the first modification example of the present embodiment, and corresponds to FIG. 1.

Hereinafter, in the photoconductive antenna 200 according to the first modification example of the present embodiment, members having the same functions as the configuration members of the aforementioned photoconductive antenna 100 according to the present embodiment are assigned the same reference numerals and signs, and thus the detailed description thereof will be omitted. The same is true of a photoconductive antenna according to a second modification example of the present embodiment described below.

As shown in FIG. 6, the photoconductive antenna 200 is different from the aforementioned photoconductive antenna 100, in that an insulating layer 40 is included therein.

The insulating layer 40 is located between the second layer 20 and the first electrode 30, and between the second layer 20 and the second electrode 32. Specifically, the insulating layer 40 is located on the second layer 20, and the electrodes 30 and 32 are located on the insulating layer 40.

The insulating layer 40 is, for example, an SiO₂ layer. The thickness of the insulating layer 40 is of such an extent that a voltage can be applied to the second layer 20 by the electrodes 30 and 32. The insulating layer 40 transmits at least a portion of a light pulse. The insulating layer 40 is formed by, for example, a CVD method.

In the photoconductive antenna 200, a breakdown voltage can be made to be higher by the insulating layer 40. That is, a flow of a current between the electrodes 30 and 32 can be suppressed by the insulating layer 40. As a result, in the photoconductive antenna 200, it is possible to have high reliability, and to achieve a reduction in power consumption.

### 3.2. Second Modification Example

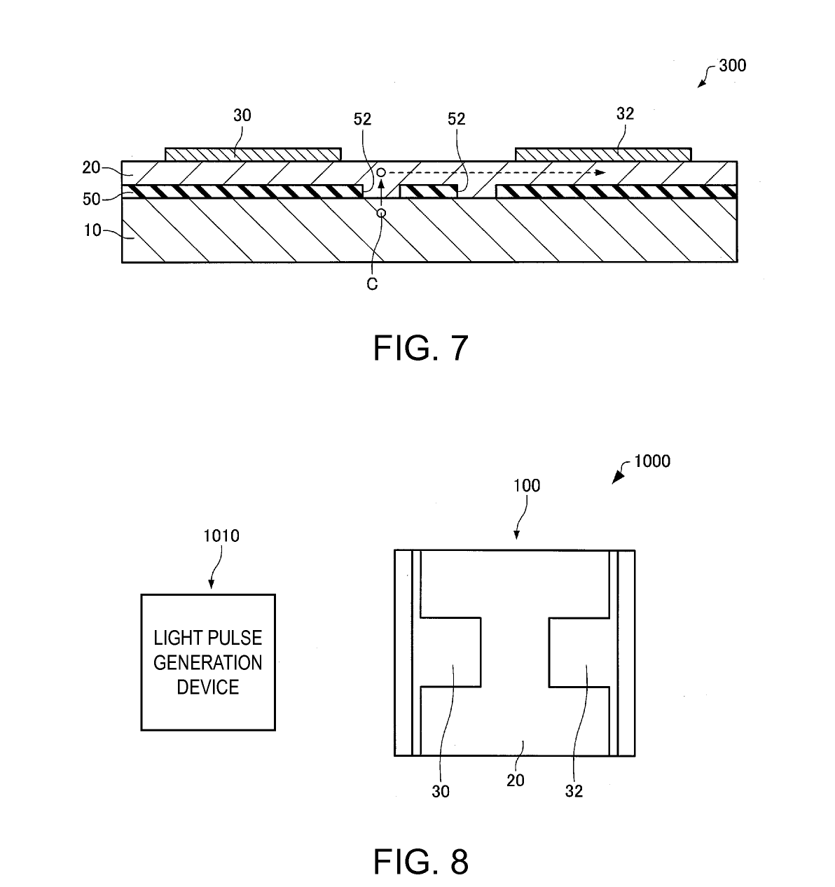

Next, a photoconductive antenna according to a second modification example of the present embodiment will be described with reference to the accompanying drawings. FIG. 7 is a cross-sectional view schematically illustrating a photoconductive antenna 300 according to the second modification example of the present embodiment, and corresponds to FIG. 1.

As shown in FIG. 7, the photoconductive antenna 300 is different from the aforementioned photoconductive antenna 100, in that a third layer 50 is included therein.

The third layer 50 is located on the first layer 10. The third layer 50 is located between the first layer 10 and the second layer 20. Openings 52 are provided in the third layer 50. In the shown example, two opening 52 are provided, but the number thereof is not particularly limited. The openings 52 are filled with the second layer 20. The carriers C generated in the first layer 10 pass through, for example, the openings 52, and then transfer through the second layer 20 from the first electrode 30 side to the second electrode 32 side.

The third layer 50 is, for example, a layer in which the SiC layer 22 (see FIGS. 3 and 4) can be laminated by epitaxial growth. That is, in a method of manufacturing the photoconductive antenna 300, the SiC layer 22 can be epitaxially grown on the third layer 50 by an MOCVD method or an MBE method. Further, the openings 52 provided in the third layer 50 can be filled with the SiC layer 22 which is epitaxially grown. Specifically, the third layer 50 is an SiO₂ layer.

The third layer 50 is formed by, for example, a CVD method. The openings 52 are formed, for example, by patterning the third layer 50 using photolithography and etching.

In the photoconductive antenna 300, as described later, the SiC layer 22 can be epitaxially grown by the third layer 50.

Meanwhile, although not shown in the drawing, the photoconductive antenna 300 may include the insulating layer 40 located between the second layer 20 and the first electrode 30 and between the second layer 20 and the second electrode 32, as in the aforementioned photoconductive antenna 200.

### 4. Terahertz Wave Generation Device

Next, a terahertz wave generation device 1000 according to the present embodiment will be described with reference to the accompanying drawings. FIG. 8 is a diagram illustrating a configuration of the terahertz wave generation device 1000 according to the present embodiment.

As shown in FIG. 8, the terahertz wave generation device 1000 includes a light pulse generation device 1010, and the photoconductive antenna according to the invention. Hereinafter, as the photoconductive antenna according to the invention, an example in which the photoconductive antenna 100 is used will be described.

The light pulse generation device 1010 generates a light pulse (for example, light pulse P shown in FIG. 1) which is excitation light. The light pulse generation device 1010 irradiates the photoconductive antenna 100. The width of the light pulse generated by the light pulse generation device 1010 is, for example, equal to or greater than 1 fs and equal to or less than 800 fs. As the light pulse generation device 1010, for example, a femtosecond fiber laser and a titanium sapphire laser are used.

As described above, the photoconductive antenna 100 can generate a terahertz wave by irradiation with a light pulse.

The terahertz wave generation device 1000 includes the photoconductive antenna 100, and thus can generate a terahertz wave having a large intensity.

### 5. Imaging Device

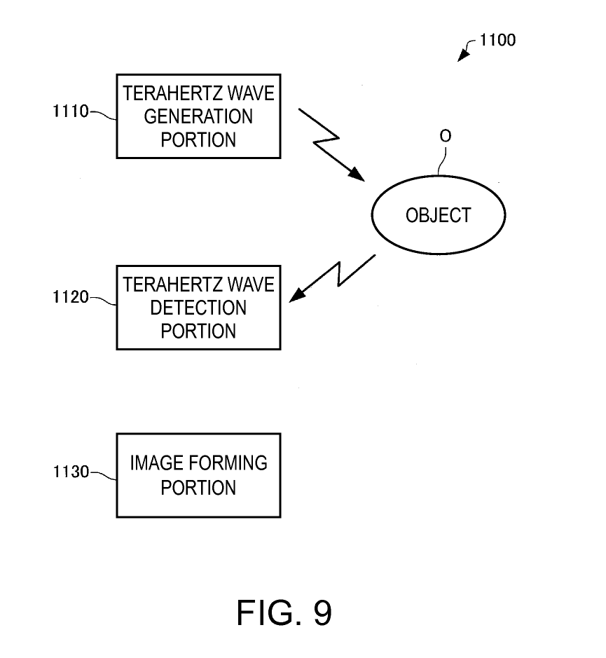

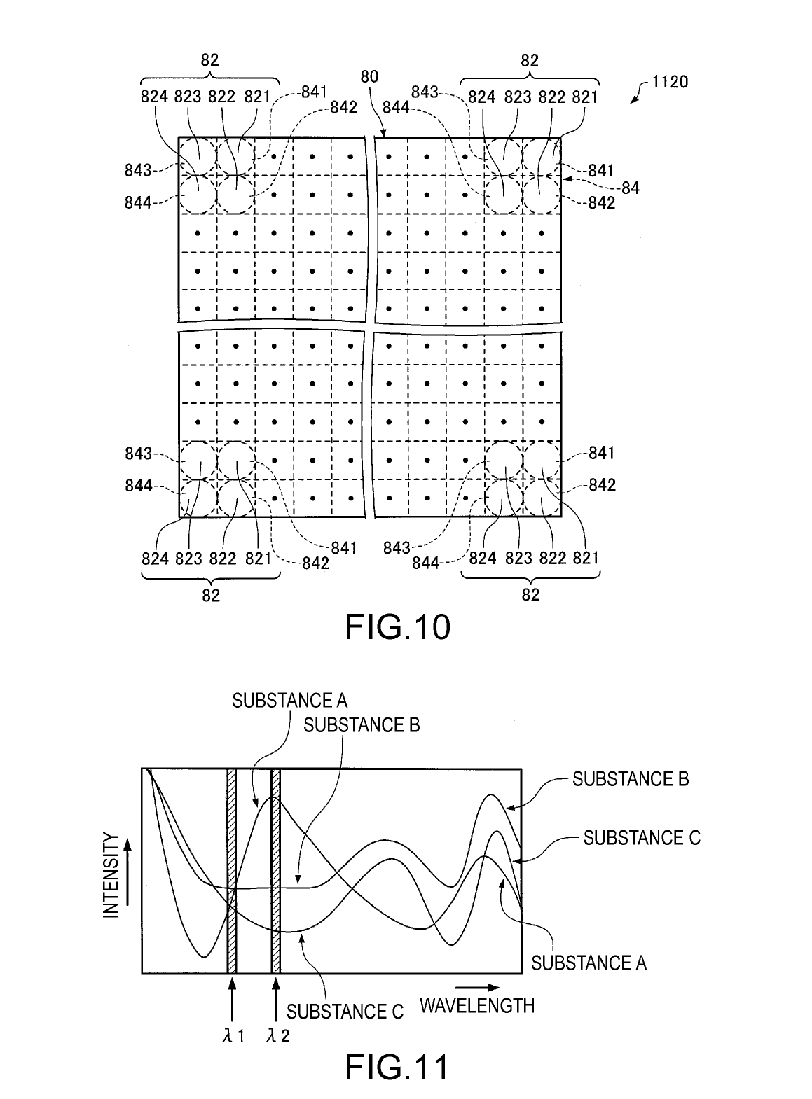

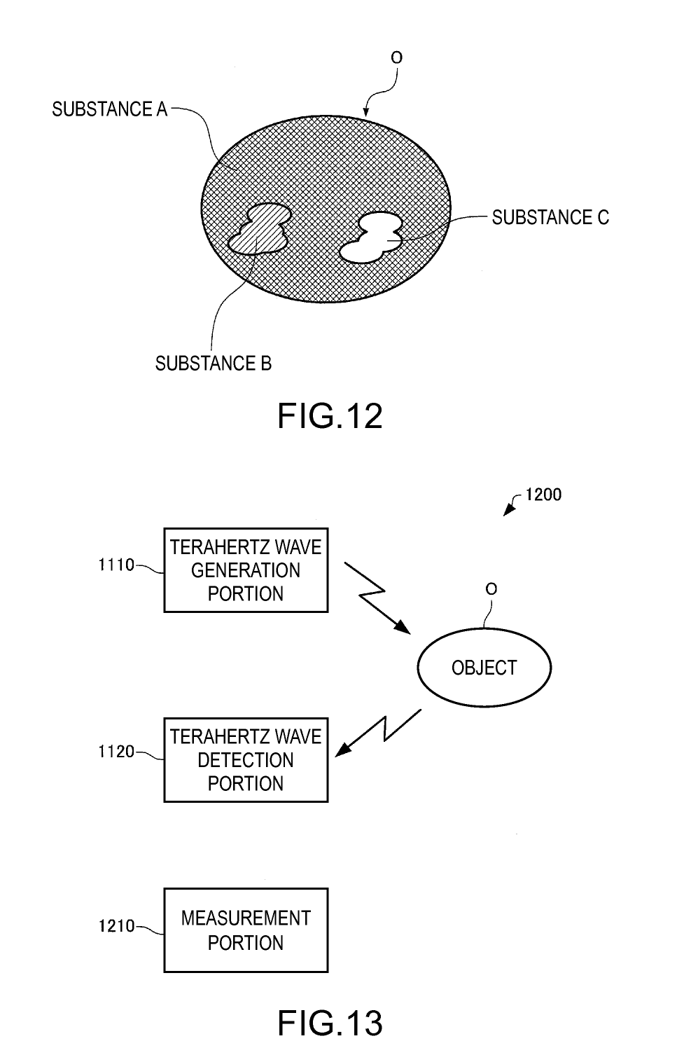

Next, an imaging device 1100 according to the present embodiment will be described with reference to the accompanying drawings. FIG. 9 is a block diagram illustrating the imaging device 1100 according to the present embodiment. FIG. 10 is a plan view schematically illustrating a terahertz wave detection portion 1120 of the imaging device 1100 according to the present embodiment. FIG. 11 is a graph illustrating a spectrum of an object in a terahertz band. FIG. 12 is an image diagram illustrating a distribution of substances A, B and C of the object.

As shown in FIG. 9, the imaging device 1100 includes a terahertz wave generation portion 1110 that generates a terahertz wave, a terahertz wave detection portion 1120 that detects a terahertz wave emitted from the terahertz wave generation portion 1110 and passing through an object O or a terahertz wave reflected from the object O, and an image forming portion 1130 that generates an image of the object O, that is, image data on the basis of a detection result of the terahertz wave detection portion 1120.

As the terahertz wave generation portion 1110, a terahertz wave generation device according to the invention can be used. Here, a case will be described in which the terahertz wave generation device 1000 is used as the terahertz wave generation device according to the invention.

The terahertz wave detection portion 1120 to be used includes a filter 80 that transmits a terahertz wave having an objective wavelength and a detection portion 84 that detects the terahertz wave having an objective wavelength having passed through the filter 80, as shown in FIG. 10. In addition, the detection portion 84 to be used has, for example, a function of converting a terahertz wave into heat to detect the converted terahertz wave, that is, a function capable of converting a terahertz wave into heat to detect energy (intensity) of the terahertz wave. Such a detection portion includes, for example, a pyroelectric sensor, a bolometer or the like. Meanwhile, the configuration of the terahertz wave detection portion 1120 is not limited to the above-mentioned configuration.

In addition, the filter 80 includes a plurality of pixels (unit filter portions) 82 which are arranged two-dimensionally. That is, the respective pixels 82 are arranged in a matrix.

In addition, each of the pixels 82 includes a plurality of regions that transmit terahertz waves having wavelengths different from each other, that is, a plurality of regions in which wavelengths of terahertz waves to be transmitted (hereinafter, referred to as “transmission wavelengths”) are different from each other. Meanwhile, in the shown configuration, each of the pixels 82 includes a first region 821, a second region 822, a third region 823, and a fourth region 824.

In addition, the detection portion 84 includes a first unit detection portion 841, a second unit detection portion 842, a third unit detection portion 843 and a fourth unit detection portion 844 which are respectively provided corresponding to the first region 821, the second region 822, the third region 823 and the fourth region 824 of each pixel 82 of the filter 80. Each first unit detection portion 841, each second unit detection portion 842, each third unit detection portion 843 and each fourth unit detection portion 844 convert terahertz waves which have respectively passed through the first region 821, the second region 822, the third region 823 and the fourth region 824 of each pixel 82 into heat to detect the converted terahertz waves. Thereby, it is possible to reliably detect the terahertz waves having four objective wavelengths in the respective regions of each pixel 82.

Next, an example of use of the imaging device 1100 will be described.

First, the object O targeted for spectroscopic imaging is constituted by three substances A, B and C. The imaging device 1100 performs spectroscopic imaging on the object O. In addition, here, as an example, the terahertz wave detection portion 1120 is assumed to detect a terahertz wave reflected from the object O.

In addition, the first region 821 and the second region 822 are used in each pixel 82 of the filter 80 of the terahertz wave detection portion 1120. When the transmission wavelength of the first region 821 is set to λ1, the transmission wavelength of the second region 822 is set to λ2, the intensity of a component having the wavelength λ1 of the terahertz wave reflected from the object O is set to α1, and the intensity of a component having the wavelength λ2 is set to α2, the transmission wavelength λ1 of the first region 821 and the transmission wavelength λ2 of the second region 822 are set so that differences (α2−α1) between the intensity α2 and the intensity α1 can be remarkably distinguished from each other in the substance A, the substance B and the substance C.

As shown in FIG. 11, in the substance A, the difference (α2−α1) between the intensity α2 of the component having the wavelength λ2 of the terahertz wave reflected from the object O and the intensity α1 of the component having the wavelength λ1 is set to a positive value. In addition, in the substance B, the difference (α2−α1) between the intensity α2 and the intensity α1 is set to zero. In addition, in the substance C, the difference (α2−α1) between the intensity α2 and the intensity α1 is set to a negative value.

When the spectroscopic imaging of the object O is performed by the imaging device 1100, a terahertz wave is first generated by the terahertz wave generation portion 1110, and the object O is irradiated with the terahertz wave. The terahertz wave reflected from the object O is then detected as α1 and α2 in the terahertz wave detection portion 1120. The detection results are sent out to the image forming portion 1130. Meanwhile, the irradiation of the object O with the terahertz wave and the detection of the terahertz wave reflected from the object O are performed on the entire object O.

In the image forming portion 1130, the difference (α2−α1) between the intensity α2 of the component having the wavelength λ2 of the terahertz wave having passed through the second region 822 of the filter 80 and the intensity α1 of the component having the wavelength λ1 of the terahertz wave having passed through the first region 821 is obtained on the basis of the above detection results. In the object O, a region in which the difference is set to a positive value is determined to be the substance A, a region in which the difference is set to zero is determined to be the substance B, and a region in which the difference is set to a negative value is determined to be the substance C, and the respective regions are specified.

In addition, in the image forming portion 1130, image data of an image indicating the distribution of the substances A, B and C of the object O is created as shown in FIG. 12. The image data is sent out from the image forming portion 1130 to a monitor which is not shown, and the image indicating the distribution of the substances A, B and C of the object O is displayed on the monitor. In this case, for example, using color coding, the region in which the substance A of the object O is distributed is displayed in a black color, the region in which the substance B is distributed is displayed in an ash color, and the region in which the substance C is distributed is displayed in a white color. In the imaging device 1100, in this manner, the identification of each substance constituting the object O and the distribution measurement of each substance can be simultaneously performed.

Meanwhile, the application of the imaging device 1100 is not limited to the above. For example, a person is irradiated with a terahertz wave, the terahertz wave transmitted or reflected through or from the person is detected, and a process is performed in the image forming portion 1130, and thus it is possible to discriminate whether the person carries a pistol, a knife, an illegal medicinal substance, and the like.

The imaging device 1100 includes the photoconductive antenna 100 which is capable of generating a terahertz wave having a large intensity. Therefore, the imaging device 1100 can have high detection sensitivity.

### 6. Measurement Device

Next, a measurement device 1200 according to the present embodiment will be described with reference to the accompanying drawings. FIG. 13 is a block diagram illustrating the measurement device 1200 according to the present embodiment. In the measurement device 1200 according to the embodiment described below, members having the same function as the configuration members of the above-mentioned imaging device 1100 are assigned the same reference numerals and signs, and thus the detailed description thereof will be omitted.

As shown in FIG. 13, the measurement device 1200 includes a terahertz wave generation portion 1110 that generates a terahertz wave, a terahertz wave detection portion 1120 that detects a terahertz wave emitted from the terahertz wave generation portion 1110 and passing through the object O or a terahertz wave reflected from the object O, and a measurement portion 1210 that measures the object O on the basis of a detection result of the terahertz wave detection portion 1120.

Next, an example of use of the measurement device 1200 will be described. When the spectroscopic measurement of the object O is performed by the measurement device 1200, a terahertz wave is first generated by the terahertz wave generation portion 1110, and the object O is irradiated with the terahertz wave. The terahertz wave having passed through the object O or a terahertz wave reflected from the object O is then detected in the terahertz wave detection portion 1120. The detection results are sent out to the measurement portion 1210. Meanwhile, the irradiation of the object O with the terahertz wave and the detection of the terahertz wave having passed through the object O or the terahertz wave reflected from the object O are performed on the entire object O.

In the measurement portion 1210, the intensity of each terahertz wave having passed through the first region 821, the second region 822, the third region 823 and the fourth region 824 of each pixel 82 of the filter 80 is ascertained from the above detection results, and the analysis or the like of components of the object O and the distribution thereof is performed.

The measurement device 1200 includes the photoconductive antenna 100 which is capable of generating a terahertz wave having a large intensity. Therefore, the measurement device 1200 can have high detection sensitivity.

### 7. Camera

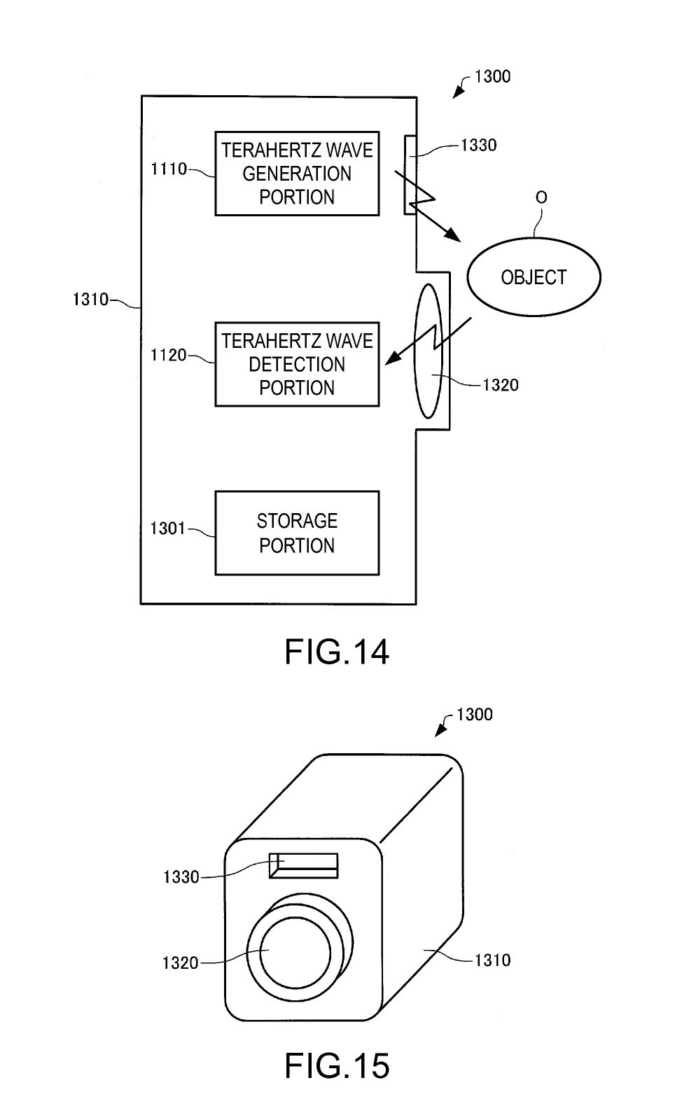

Next, a camera 1300 according to the present embodiment will be described with reference to the accompanying drawings. FIG. 14 is a block diagram illustrating the camera 1300 according to the present embodiment. FIG. 15 is a perspective view schematically illustrating the camera 1300 according to the present embodiment. In the camera 1300 according to the present embodiment described below, members having the same functions as the configuration members of the aforementioned imaging device 1100 are assigned the same reference numerals and signs, and thus the detailed description thereof will be omitted.

As shown in FIGS. 14 and 15, the camera 1300 includes a terahertz wave generation portion 1110 that generates a terahertz wave, a terahertz wave detection portion 1120 that detects a terahertz wave emitted from the terahertz wave generation portion 1110 and reflected from the object O or a terahertz wave passing through the object O, and a storage portion 1301. The respective portions 1110, 1120, and 1301 are contained in a housing 1310 of the camera 1300. In addition, the camera 1300 includes a lens (optical system) 1320 that converges (images) the terahertz wave reflected from the object O onto the terahertz wave detection portion 1120, and a window 1330 that emits the terahertz wave generated in the terahertz wave generation portion 1110 to the outside of the housing 1310. The lens 1320 and the window 1330 are constituted by members, such as silicon, quartz, or polyethylene, which transmit and refract the terahertz wave. Meanwhile, the window 1330 may have a configuration in which an opening is simply provided as in a slit.

Next, an example of use of the camera 1300 will be described. When the object O is imaged by the camera 1300, a terahertz wave is first generated by the terahertz wave generation portion 1110, and the object O is irradiated with the terahertz wave. The terahertz wave reflected from the object O is converged (imaged) onto the terahertz wave detection portion 1120 by the lens 1320 to detect the converged wave. The detection results are sent out to the storage portion 1301 and are stored therein. Meanwhile, the irradiation of the object O with the terahertz wave and the detection of the terahertz wave reflected from the object O are performed on the entire object O. In addition, the above detection results can also be transmitted to, for example, an external device such as a personal computer. In the personal computer, each process can be performed on the basis of the above detection results.

The camera 1300 includes the photoconductive antenna 100 which is capable of generating a terahertz wave having a large intensity. Therefore, the camera 1300 can have high detection sensitivity.

The above-mentioned embodiments and modification examples are illustrative examples, and are not limited thereto. For example, each of the embodiments and each of the modification examples can also be appropriately combined.

The invention includes substantially the same configurations (for example, configurations having the same functions, methods and results, or configurations having the same objects and effects) as the configurations described in the embodiments. In addition, the invention includes a configuration obtained by replacing non-essential portions in the configurations described in the embodiments. In addition, the invention includes a configuration that exhibits the same operations and effects as those of the configurations described in the embodiment or a configuration capable of achieving the same objects. In addition, the invention includes a configuration obtained by adding the configurations described in the embodiments to known techniques.

The entire disclosure of Japanese Patent Application No. 2014-015707, filed Jan. 30, 2014 is expressly incorporated by reference herein.

What is claimed is:

1. A photoconductive antenna that generates a terahertz wave by irradiation with a light pulse, comprising:
a first layer that has carriers formed therein by irradiation with the light pulse;
a second layer, located above the first layer, which has carrier mobility larger than carrier mobility of the first layer; and
a first electrode and a second electrode, located above the second layer, which apply a voltage to the second layer.

2. The photoconductive antenna according to claim 1, wherein the first layer is constituted by a semi-insulating substrate.

3. The photoconductive antenna according to claim 2, wherein the first layer is formed of GaAs.

4. The photoconductive antenna according to claim 1, wherein the first layer is formed of silicon.

5. The photoconductive antenna according to claim 1, wherein the second layer is formed of a material containing carbon as a main ingredient.

6. The photoconductive antenna according to claim 5, wherein the second layer is formed of graphene.

7. The photoconductive antenna according to claim 5, wherein the second layer includes a carbon nanotube.

8. The photoconductive antenna according to claim 1, further comprising an insulating layer which is located between the second layer and the first electrode, and between the second layer and the second electrode.

9. A terahertz wave generation device comprising:
a light pulse generation device that generates a light pulse; and
the photoconductive antenna according to claim 1 which generates the terahertz wave by irradiation with the light pulse.

10. A terahertz wave generation device comprising:
a light pulse generation device that generates a light pulse; and
the photoconductive antenna according to claim 2 which generates the terahertz wave by irradiation with the light pulse.

11. A terahertz wave generation device comprising:
a light pulse generation device that generates a light pulse; and
the photoconductive antenna according to claim 5 which generates the terahertz wave by irradiation with the light pulse.

12. A camera comprising:
a light pulse generation device that generates a light pulse;
the photoconductive antenna according to claim 1 which generates the terahertz wave by irradiation with the light pulse;
a terahertz wave detection portion that detects the terahertz wave emitted from the photoconductive antenna and passing through an object or the terahertz wave reflected from the object; and
a storage portion that stores detection results of the terahertz wave detection portion.

13. A camera comprising:
a light pulse generation device that generates a light pulse;
the photoconductive antenna according to claim 2 which generates the terahertz wave by irradiation with the light pulse;
a terahertz wave detection portion that detects the terahertz wave emitted from the photoconductive antenna and passing through an object or the terahertz wave reflected from the object; and
a storage portion that stores detection results of the terahertz wave detection portion.

14. A camera comprising:
a light pulse generation device that generates a light pulse;
the photoconductive antenna according to claim 5 which generates the terahertz wave by irradiation with the light pulse;
a terahertz wave detection portion that detects the terahertz wave emitted from the photoconductive antenna and passing through an object or the terahertz wave reflected from the object; and
a storage portion that stores detection results of the terahertz wave detection portion.

15. An imaging device comprising:
a light pulse generation device that generates a light pulse;
the photoconductive antenna according to claim 1 which generates the terahertz wave by irradiation with the light pulse;
a terahertz wave detection portion that detects the terahertz wave emitted from the photoconductive antenna and passing through an object or the terahertz wave reflected from the object; and
an image forming portion that generates an image of the object on the basis of detection results of the terahertz wave detection portion.

16. An imaging device comprising:
a light pulse generation device that generates a light pulse;
the photoconductive antenna according to claim 2 which generates the terahertz wave by irradiation with the light pulse;
a terahertz wave detection portion that detects the terahertz wave emitted from the photoconductive antenna and passing through an object or the terahertz wave reflected from the object; and
an image forming portion that generates an image of the object on the basis of detection results of the terahertz wave detection portion.

17. An imaging device comprising:
a light pulse generation device that generates a light pulse;
the photoconductive antenna according to claim 5 which generates the terahertz wave by irradiation with the light pulse;
a terahertz wave detection portion that detects the terahertz wave emitted from the photoconductive antenna and passing through an object or the terahertz wave reflected from the object; and
an image forming portion that generates an image of the object on the basis of detection results of the terahertz wave detection portion.

18. A measurement device comprising:
a light pulse generation device that generates a light pulse;
the photoconductive antenna according to claim 1 which generates the terahertz wave by irradiation with the light pulse;
a terahertz wave detection portion that detects the terahertz wave emitted from the photoconductive antenna and passing through an object or the terahertz wave reflected from the object; and
a measurement portion that measures the object on the basis of detection results of the terahertz wave detection portion.

19. A measurement device comprising:
a light pulse generation device that generates a light pulse;
the photoconductive antenna according to claim 2 which generates the terahertz wave by irradiation with the light pulse;
a terahertz wave detection portion that detects the terahertz wave emitted from the photoconductive antenna and passing through an object or the terahertz wave reflected from the object; and
a measurement portion that measures the object on the basis of detection results of the terahertz wave detection portion.

20. A measurement device comprising:
a light pulse generation device that generates a light pulse;
the photoconductive antenna according to claim 5 which generates the terahertz wave by irradiation with the light pulse;
a terahertz wave detection portion that detects the terahertz wave emitted from the photoconductive antenna and passing through an object or the terahertz wave reflected from the object; and
a measurement portion that measures the object on the basis of detection results of the terahertz wave detection portion.
